(19) United States
(12) Patent Application Publication
(10) Pub. No.: US 2016/0056242 A1
(43) Pub. Date: Feb. 25, 2016

(54) SILICON CARBIDE SEMICONDUCTOR DEVICE

(71) Applicant: Sumitomo Electric Industries, Ltd., Osaka-shi (JP)

(72) Inventor: Takeyoshi Masuda, Osaka-shi (JP)

(21) Appl. No.: 14/795,669

(22) Filed: Jul. 9, 2015

(30) Foreign Application Priority Data
Aug. 20, 2014 (JP) 2014-167676

(51) Int. Cl. H01L 29/16; H01L 29/423; H01L 27/088; H01L 29/778

(52) U.S. Cl. CPC H01L 29/1608; H01L 29/7788; H01L 29/4236; H01L 27/088

(57) ABSTRACT

A silicon carbide substrate is formed of a first region and a second region. The first region includes a first impurity region, a second impurity region, and a first portion forming part of a third impurity region. The second region includes a second portion, the second portion forming part of the third impurity region and being connected to the first portion. Further, a gate insulating film is in contact with the first impurity region, the second impurity region, and the first portion of the third impurity region. An upper electrode is disposed on the second portion of the second region. A channel region extends linearly along a first direction when viewed along a direction perpendicular to a first main surface. The second portion is provided to connect a plurality of impurity region portions together. Consequently, a silicon carbide semiconductor device capable of achieving reduced on-resistance is provided.

### BACKGROUND OF THE INVENTION

1. Field of the Invention

The present invention relates to silicon carbide semiconductor devices, and more particularly to a silicon carbide semiconductor device including a gate insulating film.

2. Description of the Background Art

In recent years, silicon carbide has been increasingly employed as a material for a semiconductor device in order to allow a higher breakdown voltage, lower loss and. the use in a high-temperature environment and the like of the semiconductor device. Silicon carbide is a wide band gap semiconductor having a band gap wider than that of silicon which has been conventionally and widely used as a material for a semiconductor device. By employing the silicon carbide as a material for a semiconductor device, therefore, a higher breakdown voltage, lower on-resistance and the like of the semiconductor device can be achieved. A semiconductor device made of silicon carbide is also advantageous in that performance degradation is small when used in a high-temperature environment as compared to a semiconductor device made: of silicon.

For example, Japanese Patent Laying-Open No. 2010-147228 describes a trench type MOSFET (Metal Oxide Semiconductor Field Effect Transistor) made of silicon carbide. This MOSFET includes a trench having one direction as a longitudinal direction, and deep layers provided to extend in a direction intersecting the longitudinal direction of the trench and disposed below a base region.

### SUMMARY OF THE INVENTION

In the above MOSFET, since the deep layers are disposed directly below channels formed to face side surfaces of the trench, the channels near regions where deep layers and the trench intersect each other cannot contribute as a current path, resulting in an increase in on-resistance of the MOSFET.

In addition, according to the above MOSFET, a source electrode is disposed between two adjacent trenches. It is thus required to have space of a certain size between the two adjacent trenches, resulting in inability to increase the channel density per unit area. This has resulted in an increase in on-resistance of the MOSFET.

An object of one embodiment of the present invention is to provide a silicon carbide semiconductor device capable of achieving reduced on-resistance.

A silicon carbide semiconductor device according to one embodiment of the present invention includes a silicon carbide substrate, a gate insulating film, an upper electrode, and a lower electrode. The silicon carbide substrate has a first main surface and a second main surface opposite to the first main surface. The silicon carbide substrate includes a first impurity region having a first conductivity type, a second impurity region being in contact with the first impurity region and having a second conductivity type different from the first conductivity type, and a third impurity region having the first conductivity type, being separated from the first impurity region by the second impurity region, and forming the first main surface. The silicon carbide substrate is formed of a first region and a second region adjacent to each other when viewed from a direction perpendicular to the first main surface. The first region includes the first impurity region, the second impurity region, and a first portion forming part of the third impurity region. The second region includes a second portion, the second portion forming part of the third impurity region and being connected to the first portion. Further, the gate insulating film is in contact, with the first impurity region, the second impurity region, and the first portion of the third impurity region. The upper electrode is disposed on the second portion of the second region. The lower electrode is disposed on the second main surface. The second impurity region has a channel region in contact with the gate insulating film. The channel region extends linearly along a first direction when viewed along the direction perpendicular to the first main surface. The first portion of the third impurity region includes a plurality of impurity region portions disposed in alignment with each other along a second direction, the second direction being parallel to the first main surface and perpendicular to the first direction. The second portion is provided to connect the plurality of impurity region portions together.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing the structure of a silicon carbide semiconductor device when viewed along line I-I in FIG. 3.

FIG. 2 is a schematic sectional view showing the structure of the silicon carbide semiconductor device when viewed along line II-II in FIG. 3.

FIG. 3 is a schematic plan view showing the structure of a first example of a silicon carbide substrate of a silicon carbide semiconductor device according to a first embodiment of the present invention,

FIG. 4 is a schematic plan view showing channel regions of the silicon carbide semiconductor device according to the first embodiment of the present invention.

FIG. 5 is a schematic plan view showing the structure of a second example of the silicon carbide substrate of the silicon carbide semiconductor device according to the first embodiment of the present invention.

FIG. 6 is a schematic plan view showing the structure of an upper electrode and agate electrode of the silicon carbide semiconductor device according to the first embodiment of the present invention.

FIG. 7 is a. schematic plan view showing the structure of an embedded region of the silicon carbide semiconductor device according to the first embodiment of the present invention.

FIG. 8 is a schematic sectional view schematically illustrating a first step of a method of manufacturing the silicon carbide semiconductor device according to the first embodiment of the present invention.

FIG. 9 is a schematic sectional view schematically illustrating a second step of the method of manufacturing the silicon carbide semiconductor device according to the first embodiment of the present invention.

FIG. 10 is a schematic sectional view schematically illustrating a third step of the method of manufacturing the silicon carbide semiconductor device according to the first embodiment of the present invention.

FIG. 11 is a schematic sectional view schematically illustrating a fourth step of the method of manufacturing the silicon carbide semiconductor device according to the first embodiment of the present invention.

FIG. 12 is a schematic sectional view schematically illustrating a fifth step of the method of manufacturing the silicon carbide semiconductor device according to the first embodiment of the present invention.

FIG. 13 is a schematic sectional view showing the structure of a silicon carbide: semiconductor device when viewed along line XIII-XIII in FIG. 15.

FIG. 14 is a schematic sectional view showing the structure of the silicon carbide semiconductor device when viewed along line XIV-XIV in FIG. 15.

FIG. 15 is a schematic plan view showing the structure of a first example of a silicon carbide substrate of a silicon carbide semiconductor device according to a second embodiment of the present invention.

FIG. 16 is a schematic plan view showing channel regions of the silicon carbide semiconductor device according to the second embodiment of the present invention.

FIG. 17 is a schematic plan view showing the structure of a second example of the silicon carbide substrate of the silicon carbide semiconductor device according to the second embodiment of the present invention.

FIG. 18 is a schematic plan view showing the structure of an upper electrode and agate electrode of the silicon carbide semiconductor device according to the second embodiment of the present invention.

FIG. 19 is a diagram showing relation between area occupancy of the embedded region and specific on-resistance.

### DETAILED DESCRIPTION OF THE INVENTION

### Description of Embodiments of the Present Invention

As a result of a detailed study on methods of reducing the on-resistance of a silicon carbide semiconductor device, the present inventor conceived of one embodiment of the present invention based on the following findings.

The on-resistance of a silicon carbide semiconductor device is generally divided into contact resistance between an upper electrode (source electrode) and a silicon carbide substrate, channel resistance, path resistance from the upper electrode to channels, resistance of an epitaxial layer, and resistance of a silicon carbide single-crystal substrate. Of these resistances, the channel resistance constitutes a large percentage of the overall on-resistance. The present inventor thus examined methods of effectively reducing the channel resistance.

Usually, an upper electrode is provided in the vicinity of channels so as to pass a current efficiently through the channels. If an upper electrode is disposed in the vicinity of channels, however, a channel cannot be formed in a region where the upper electrode is formed, resulting in inability to increase the channel density per unit area. Accordingly, a silicon carbide substrate is partitioned into a first region where channels are formed and a second region where an upper electrode is formed, in which the channels are disposed at high densities in the first region and the upper electrode for passing a current through the channels is formed in the second region. Consequently, the channel resistance can be effectively reduced. Meanwhile, if the upper electrode is disposed in the second region away from the channels, the path resistance from the upper electrode to the channels increases. As a result of a detailed study, the present inventor found that the effect of reducing the on-resistance by disposing linear channels in alignment with one another at high densities was greater than the effect of increasing the on-resistance due to the increased path resistance from the upper electrode to the channels. That is, the total on-resistance can be reduced by partitioning the silicon carbide substrate into the first region where the channels are formed and the second region where the upper electrode is formed, and by disposing linear channels at high densities in the first region.

Embodiments of the present invention will now be listed and described.

(1) A silicon carbide semiconductor device according to one embodiment of the present invention includes a silicon carbide substrate 10, a gate insulating film 15, an upper electrode 16, and a lower electrode 20. Silicon carbide substrate 10 has a first main surface 10a and a second main surface 10b opposite to first main surface 10a. Silicon carbide substrate 10 includes a first impurity region 12a having a first conductivity type, a second impurity region 13a being in contact with first impurity region 12a and having a second conductivity type different from the first conductivity type, and a third impurity region 14 having the first conductivity type, being separated from first impurity region 12a by second impurity region 13a, and forming first main surface 10a. Silicon carbide substrate 10 is formed of a first region R1 and a second region R2 adjacent to each other when viewed from a direction perpendicular to first main surface 10a. First region R1 includes first impurity region 12a, second impurity region 13a, and a first portion 14a forming part of third impurity region 14. Second region R2 includes a second portion 14b, the second portion forming part of third impurity region 14 and being connected to first portion 14a. Further, gate insulating film 15 is in contact with first impurity region 12a, second impurity region 13a, and first portion 14a of third impurity region 14. Upper electrode 16 is disposed on second portion 14b of second region R2. Lower electrode 20 is disposed on second main surface 10b. Second impurity region 13a has a Channel region CH in contact with gate insulating film 15. Channel region CH extends linearly along a first direction when viewed along the direction perpendicular to first main surface 10a. First portion 14a of third impurity region 14 includes a plurality of impurity region. portions 14a1 and 14a2 disposed in alignment with each other along a second direction, the second direction being parallel to the first main surface and perpendicular to the first direction. Second portion 14b is provided to connect the plurality of impurity region portions 14a1 and 14a2 together.

According to the silicon carbide semiconductor device of (1) above, the on-resistance of the silicon carbide semiconductor device can be reduced by partitioning silicon carbide substrate 10 into first region R1 where the channels are formed and second region R2 where upper electrode 16 is formed, and by disposing linear channel regions CH at high densities in first region R1 and disposing upper electrode 16 in second region R2. In addition, channel regions CH extend linearly along the first direction. Thus, there are fewer corner portions as compared to when channel regions CH have a polygonal shape. As a result, electric field concentration at the corner portions can be suppressed to thereby improve the breakdown voltage of the silicon carbide semiconductor device.

(2) Preferably, in the silicon carbide semiconductor device according to (1) above, a first trench T1 having first side surface S1 connected to first main surface: 10a and a first bottom B1 connected to first side surface S1 is provided between the plurality of impurity region portions 14a1 and 14a2. Gate insulating film 15 is in contact with first impurity region 12a, second impurity region 13a, and the plurality of impurity region portions 14a1, 14a2 at first side surface S1, and is in contact with first impurity region 12a at first bottom B1. Channel region CH is in contact with gate insulating film 15 at first side surface S1. Consequently, the on-resistance of the silicon carbide semiconductor device can be effectively reduced.

(3) Preferably, in the silicon carbide semiconductor device according to (2) above, a second trench T2 having a second side surface 52 connected to first side surface 51 of first trench T1 and a second bottom B2 connected to first bottom B1 of first trench T1 is provided in second region R2. Second side surface 52 and second. bottom B2 are each in contact with gate insulating film 15. Consequently, the on-resistance of the silicon carbide semiconductor device can be more effectively reduced.

(4) Preferably, the silicon carbide semiconductor device according to (3) above further includes a gate electrode 27 in contact with gate insulating film 15. Gate electrode 27 is provided in each of first trench T1 and second trench T2, and is also provided to traverse first trench T1 along second direction a2. Consequently, a gate electrode wiring can be formed to traverse first trench T1, thereby reducing the resistance of the gate electrode wiring.

(5) Preferably, in the silicon carbide semiconductor according to any one of (2) to (4) above, first trench T1 includes a first trench portion T11, and a second trench portion T12 separated from first trench portion T11 by impurity region portion 14a2. Silicon carbide substrate 10 further includes an embedded region 17, the embedded region being provided between second main surface 10b and second impurity region 13a, having the second conductivity type, and having an impurity concentration higher than in second impurity region 13a. A value obtained by dividing the width of embedded region 17 by the distance from a center of the bottom of first trench portion T11 to a center of the bottom of second trench portion T12 in the second direction is 0.3 or less. Consequently, the on-resistance of the silicon carbide semiconductor device can be effectively reduced while the breakdown voltage of the silicon carbide semiconductor device is maintained at a high level.

(6) Preferably, in the silicon carbide semiconductor device according to any one of (1) to (4) above, silicon carbide substrate 10 further includes an embedded region 17, the embedded region being provided between second main surface 10b and second impurity region 13a, having the second conductivity type, and having an impurity concentration higher than in second impurity region 13a. Consequently, the breakdown voltage of the silicon carbide semiconductor device can be improved.

(7) Preferably, in the silicon carbide semiconductor device according to (6) above, embedded region 17 is provided to extend from between second main surface 10b and second impurity region 13a to between upper electrode 16 and second main. surface 10b. Consequently, energy during application of a high electric filed can be released as a current to upper electrode 16.

(8) Preferably, in the silicon carbide semiconductor device according to (6) or (7) above, embedded region 17 is electrically connected to upper electrode 16. Consequently, energy during application of a high electric filed can be effectively released as a current to upper electrode 16.

(9) Preferably, in the silicon carbide semiconductor device according to any one of (6) to (8) above, embedded region 17 includes a plurality of embedded region portions 17a separated from each other by first impurity region 12a when viewed along the first direction. A width c of a portion of first impurity region 12a sandwiched between adjacent embedded region portions 17a in a direction along the second. direction is 1 μm or more and 3.5 μm or less. Consequently, the breakdown voltage of the silicon carbide semiconductor device can be improved.

(10) Preferably, in the silicon carbide semiconductor device according to (1) above, first impurity region 12a is provided between the plurality of impurity region portions 14a1 and 14a2. Gate insulating film 15 is in contact with first impurity region 12a, second impurity region 13a, and the plurality of impurity region portions 14a1, 14a2 at first main surface 10a. Consequently, the on-resistance of the planar silicon carbide semiconductor device can be reduced.

(11) Preferably, in the silicon carbide semiconductor device according to any one of (1) to (10) above, the first direction is a <11-20> direction. Consequently, a current can flow through channel region CH in a <1-100> direction, thereby effectively reducing the channel resistance. In addition, misalignment in the second direction can be reduced.

### Details of Embodiments of the Present Invention

Embodiments of the present invention will be described below with reference to the drawings. In the following drawings, the same or corresponding parts are designated by the same reference numbers and the description thereof will not be repeated. Regarding crystallographic denotation herein, an individual orientation, a group orientation, an individual plane, and a group plane are shown in [ ], < >, ( ), and { }, respectively. Although a crystallographically negative index is normally expressed by a number with a bar “−” thereabove, a negative sign herein precedes a number to indicate a crystallograplhically negative index.

### First Embodiment

The configuration of a MOSFET as a silicon carbide semiconductor device 1 according to a first embodiment of the present invention is described first.

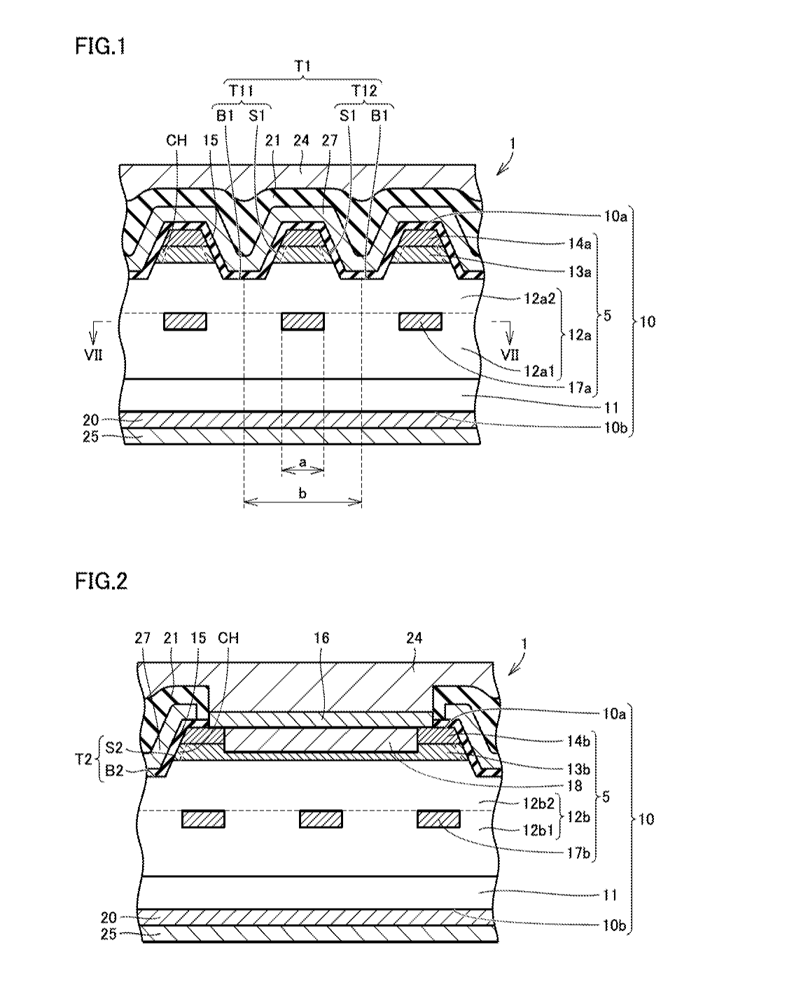

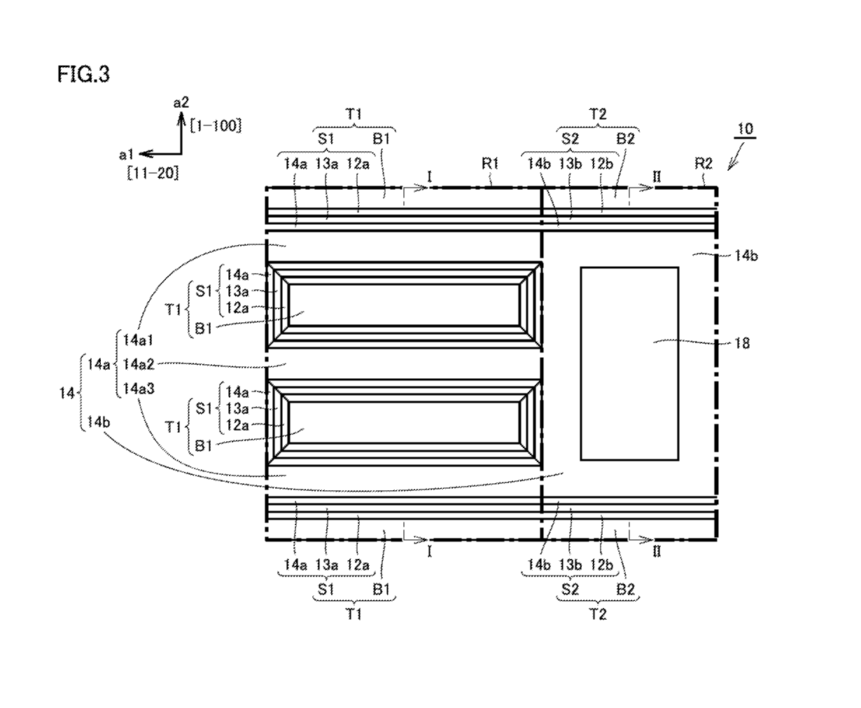

FIGS. 1 and 2 are schematic sectional views of the silicon carbide semiconductor device according to the first embodiment, and FIG. 3 is a schematic plan view of a silicon carbide substrate included in the silicon carbide semiconductor device. FIG. 1 is a schematic sectional view showing the structure of the silicon carbide semiconductor device when viewed along line I-I in FIG. 3. FIG. 2 is a schematic sectional view showing the structure of the silicon carbide semiconductor device when viewed along line II-II in FIG. 3.

Referring to FIGS. 1 and 2, a MOSFET 1 according to the first embodiment mainly includes a silicon carbide substrate 10, a gate electrode 27, a gate insulating film 15, an interlayer insulating film 21, a source electrode 16, a source wiring 24, and a drain electrode 20. Referring to FIGS. 1 and 2, silicon carbide substrate 10 has a first main surface 10a, and a second main surface 10b opposite to first main surface 10a. Silicon carbide substrate 10 mainly includes a silicon carbide single-crystal substrate 11, and a silicon carbide epitaxial layer 5 provided on silicon carbide single-crystal substrate 11.

Silicon carbide single-crystal substrate 11 is made of hexagonal silicon carbide single crystal having a polytype of 4H, for example. First main surface 10a of silicon carbide substrate 10 has a maximum diameter of for example, 150 mm, preferably not less than 150 mm. First main surface 10a. of silicon carbide substrate 10 is, for example, a {000-1} plane or a plane having an off angle of 8° or less relative to the {000-1} plane. Preferably, first main surface 10a of silicon carbide substrate 10 is, for example, a (000-1) plane or a plane having, an off angle of 8° or less relative to the (000-1) plane.

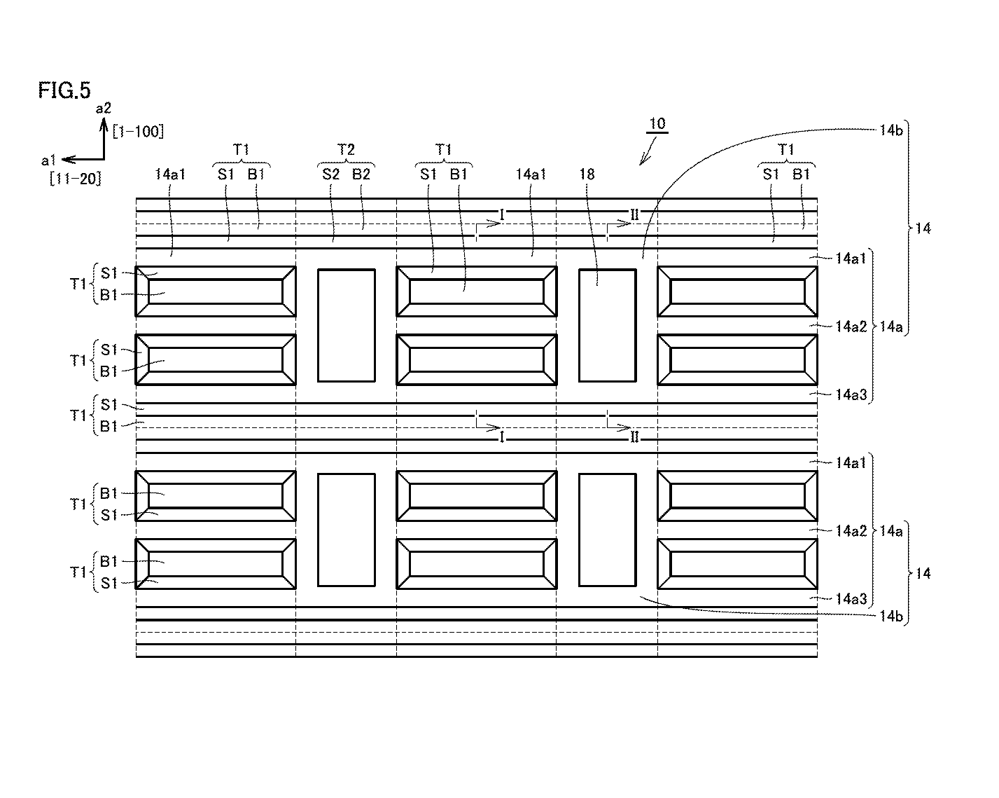

Silicon carbide epitaxial layer 5 included in silicon carbide substrate 10 mainly includes a drift region, a base region, a source region 14 (see FIG. 5), an embedded region, and a contact region 18 (see FIG. 2), The drill region and the source region each include an n type impurity for providing n type conductivity such as nitrogen or phosphorus, and have n type conductivity (first conductivity type). The base region, the embedded region and contact region 18 each include a p type impurity for providing p type conductivity such as aluminum or boron, and have p type conductivity; (second conductivity type). The base region is in contact with the drift region. Source region 14 is separated from the drift region by the base region, and forms first main surface 10a. Preferably, a concentration of the n type impurity included in source region 14 is higher than a concentration of the n type impurity included in the drift region. The concentration of the n type impurity (donor) included in source region 14 is, for example, 5×10¹⁹ cm⁻³ or more. Preferably, a concentration of the p type impurity included in contact region 18 is higher than a concentration of the p type impurity included in the base region. It is noted that the elements and the concentrations of the impurities included in the respective regions can be measured by, for example, an SCM (Scanning Capacitance Microscope) or SIMS (Secondary Ion Mass Spectrometry).

The drill region is formed of a first drift region 12a (see FIG. 1) and a second drift region 12b connected to first drift region 12a (see FIG. 2). The base region is foamed of a first base region 13a (see FIG. 1) and a second base region 13b connected to first base region 13a (see FIG. 2). The source res ion. is formed of a first source region 14a (see FIG. 1) and a second source region 14b connected to first source region 14a (see FIG. 2).

Referring to FIG. 3, when viewed from a direction perpendicular to first main surface 10a, silicon carbide substrate 10 is formed of a first region R1 and a second region R2 adjacent to each other. Referring to FIGS. 1 and 3, first region R1 includes first drift region 12a, first base region 13a, and first source region 14a forming part of source region 14. Provided in first main surface 10a of silicon carbide substrate 10 in first region R1 is a first trench T1 having a first side surface S1 connected to first main surface 10a and a first bottom B1 connected to first side surface S1. First side surface S1 of first trench T1 penetrates each of first source region 14a and first base region 13a to reach first drift region 12a. First bottom B1 of first trench T1 is located in first drift region 12a.

Referring to FIG. 3, when viewed two-dimensionally first bottom B1 of first trench T1 is provided to extend in a first direction a1. The width of first bottom B1 of first trench TI along first direction a1 is greater than the width along a second direction a2 parallel to first main surface 10a and perpendicular to first direction a1. A plurality of first trenches T1 are provided. The plurality of first trenches TI are provided in alignment with one another along second direction a2. First source region 14a includes a plurality of first source region portions 14a1, 14a2 and 14a3 disposed in alignment with one another along the second direction. Each of first source region portions 14a1, 14a2 and 14a3 is provided between the plurality of first trenches T1. First source region portions 14a1, 14a2 and 14a3 are provided on opposing sides of first trenches T1 in a direction along second direction a2.

Referring to FIGS. 2 and 3, second region R2 includes second drift region 12b second base region 13b, and second source region 14b. Second source region 14b forms part of source region 14, and is connected to first source region 14a at the boundary between first region R1 and second region R2. Second drift region 121) is connected to first drill region 12a at the boundary between first region R1 and second region R2. Second base region 13b is connected to first base region 13a at the boundary between first region R1 and second region R2. Provided in first main surface 10a of silicon carbide substrate 10 in second region R2 is a second trench 12 having a second side surface S2 connected to first main surface 10a and a second bottom B2 connected to second side surface S2. Second side surface S2 of second trench T2 penetrates each of second source region 14b and second base region 13b to reach second drift region 12b. Second bottom 132 of second trench T2 is located in second drift region 12b. Second side surface S2 of second trench T2 is connected to first side surface S1 of first trench T1 at the boundary between first region R1 and second region R2. Second bottom B2 of second trench T2 is connected to first bottom. B1 of first trench T1 at the boundary between first region R1 and second region R2. As shown in FIG. 2, second side surface S2 and second bottom B2 are each in contact with gate insulating film 15.

Referring to FIG. 3, contact region 18 and second source region 14b are provided between a plurality of second. trenches T2 in second. region R2. Contact region. 18 is not provided between the plurality of first trenches T1 in first region R1. When viewed two-dimensionally (a view along the direction perpendicular to first main surface 10a of silicon carbide substrate 10), contact region 18 is provided to be surrounded by second source region 14b. The width of contact region 18 along first direction a1 may be smaller than the width of contact region 18 along second direction a2. Second source region 141 is provided to connect together the plurality of first source region portions 14a1, 14a2 and 14a3 provided in first region R1. The plurality of first source region portions 14a1, 14a2 and 14a3 are each in contact with second source region 14b at the boundary between first region R1 and second region R2.

Gate insulating film 15 is made of a material including, for example, silicon dioxide. As shown in FIG. 1, gate insulating film 15 is in contact with first drift region 12a, first base region 13a, and first source region 14a at first side surface S1 of first trench T1, and is in contact with first drift region 12a at first bottom B1. Gate insulating film 15 is in contact with first source region portions 14a1, 14a2 and 14a3 art first side surface S1 of first trench T1. As shown in FIG. 2, gate insulating film 15 is in contact with second drift region 12b, second base region 13b, and second source. region 14b at second side surface 82 of second trench T2, and is in contact with second drift region 12b at second bottom 52. First base region 13a has a channel region CH in contact with gate insulating film 15. Second base region 13b may have a channel region CH in contact with gate insulating film 15.

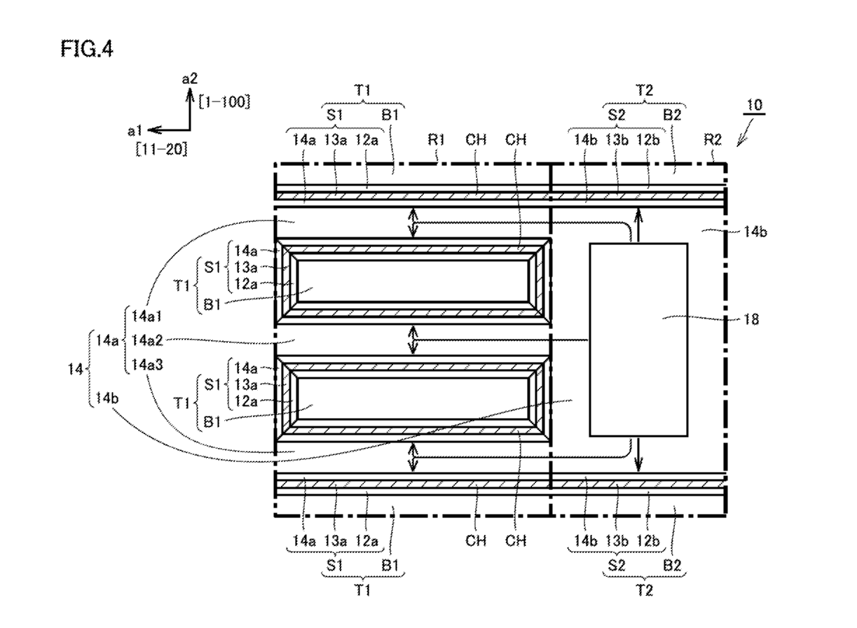

Referring to FIG. 4, the configuration of the channel region. of the MOSFET is described. In FIG. 4, regions marked with diagonal lines are channel regions CR Channel regions CH are regions where a channel is formed during ON time, and exist in the base region during OFF time as well. When viewed along the direction perpendicular to first main surface 10a, channel regions CH each have a portion extending linearly along first direction a1 Channel region CH is in contact with gate insulating film 15 at the first side surface of first trench T1. Channel region CH may be formed to surround first bottom B1 of first trench T1 when viewed two-dimensionally. That is, channel region CH may have a portion extending linearly along first direction a1, and a portion extending linearly along second direction a2. Channel region CH may be provided in second base region 13b exposed at second side surface 82 of second trench T2. The length of channel region CH (channel length) along a direction of current flow is, for example, 0.5 μm or more and 1.0 μm or less.

Arrows in FIG. 4 indicate a current flow during ON time. A current flows from source electrode 16 provided on contact region 18 and second source region 14b in second region R2 toward second source regions 14b. The current partially flows along first direction a1 from second source regions 14b toward first source regions 14a. The current passes through channel regions CH along second direction a2 perpendicular to first direction a1. The current flows from first source regions 14a toward first drill regions 12a through channel regions CR The current partially passes through channel regions CH formed to face second side surfaces 52 of second trenches T2 in second region R2, and flows toward second drill regions 120.

Referring to FIG. 5, silicon carbide substrate 10 may be formed of a plurality of units, each including first region R1 and second region R2, which are aligned with one another along each of first direction a1 and second direction a2. First region R1 includes one or more first trenches T1 Second region R2 includes one contact region 18. Specifically, first regions R1 and second regions R2 are alternately disposed along first direction a1. First regions R1 are repeatedly disposed and second regions R2 are repeatedly disposed along the second direction. First trenches T1 are provided on opposing sides of contact region 18 in a direction along first direction a1. Second trenches 12 are provided on opposing sides of contact region 18 in the direction along second direction a2. First trenches T1 are provided at intervals in the direction along first direction a1. First trenches T1 are provided at intervals in the direction along second direction a2. The distance between two adjacent first trenches T1 in the direction along first direction a1 may be greater than the distance between two adjacent second trenches 12 in the direction along second direction a2.

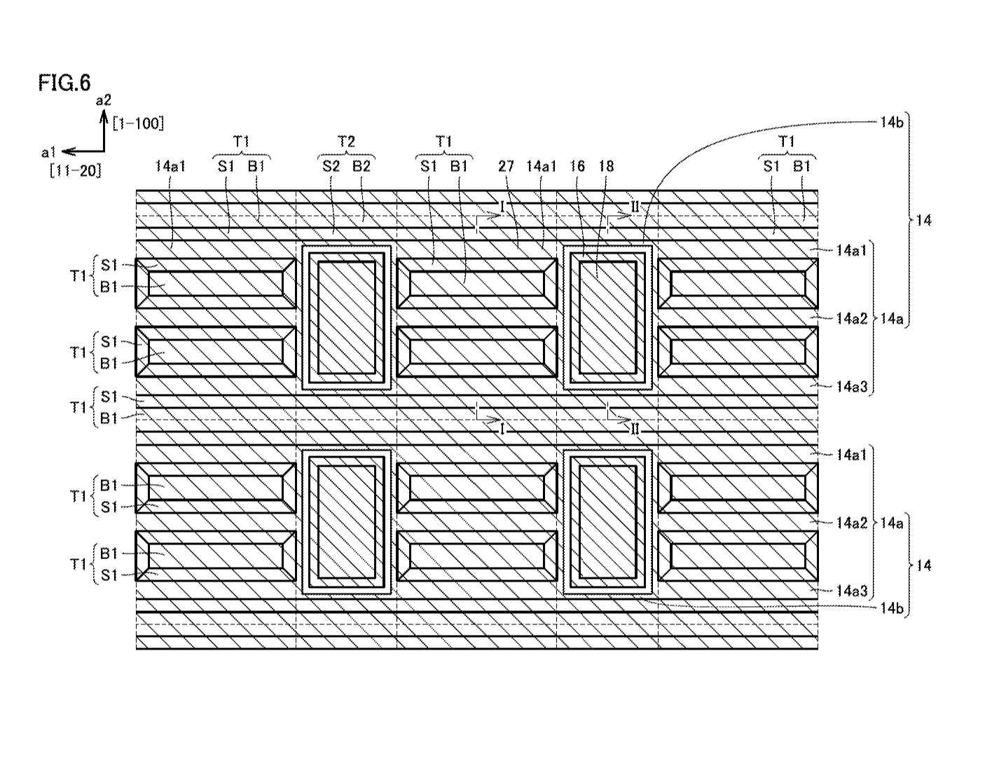

Referring to FIGS. 1 and 2, gate electrode 27 is provided in contact with gate insulating film 15. Preferably, gate electrode 27 is provided in each of first trench T1 and second trench T2, and is also provided to traverse first trench T1 along second direction a2 (see FIG. 6). Gate electrode 27 is provided to fill grooves formed by gate insulating film 15. Gate electrode 27 is made of a conductor such as polysilicon doped with an impurity, for example. Referring to FIG. 1, gate electrode 27 is provided to face first main surface 10a, first side surface S1 of first trench T1, and first bottom B1 of first trench T1. Referring to FIG. 2, gate electrode 27 is provided to face second side surface S2 of second trench 12, second bottom B2 of second trench T2, and part of first main surface 10a.

Referring to FIG. 2, source electrode 16 is in contact with each of second source region 14b and contact region 18 at first main surface 10a of silicon carbide substrate 10. Source electrode 16 includes an alloy layer in ohmic contact with second source region 14b Preferably, source electrode 16 includes an alloy layer joined to contact region 18. The alloy layer is a silicide with a metal included in source electrode 16, for example. Preferably, source electrode 16 is made of a material including Ti, Al and Si.

Referring to FIG. 6, source electrode 16 is disposed on second region R2. Preferably, source electrode 16 is disposed only on second region R2, and not on first region Source electrode 16 is disposed on second source region 14b on second region R2. Source electrode 16 is electrically connected to second source region 14b on second region R2. Preferably, source electrode 16 is provided to cover the entire contact region 18 when viewed two-dimensionally. As shown in FIG. 6, source electrodes 16 may be provided at intervals in the direction along first direction a1. Likewise, source regions 14 may be provided at intervals in the direction along second direction a2.

Referring to FIG. 6, gate electrode 27 is provided to surround source electrode 16 when viewed two-dimensionally. Gate electrode 27 is provided to traverse the plurality of first trenches T1 in the direction along second direction a2. Gate electrode 27 may be provided to cover the entire first region R1 and also to cover part of second region R2. Gate electrode 27 may be provided in a mesh-like manner when viewed two-dimensionally. Gate electrode 27 is provided to traverse each of the portions of the plurality of first source region portions 14a1, 14a2 and 14a3 (see FIG. 3) along second direction a2.

Referring to FIGS. 1 and 2 interlayer insulating film 21 is provided in a position facing first main surface 10a. of silicon carbide substrate 10, Specifically, interlayer insulating film 21 is provided in contact with each of gate electrode 27 and gate insulating film 15 so as to cover gate electrode 27. Interlayer insulating film 21. includes, for example, a TEOS (Tetra Ethyl Ortho Silicate) oxide film and PSG (Phosphorus Silicon Glass). Interlayer insulating film 21 electrically insulates gate electrode 27 and source electrode 16 from each other. Source wiring 24 is provided to cover interlayer insulating film 21 and be in contact with source electrode 16. Source wiring 24 is electrically connected to second source region 14b with source electrode 16 interposed therebetween. Source wiring 24 is made of a material including, for example, AlSiCu. Source wiring 24 may be provided on each of first region R1 and second region R2.

Drain electrode 20 (lower electrode 20) is disposed on second main surface 10b of silicon carbide substrate 10. Drain electrode 20 is in contact with silicon carbide single-crystal substrate 11 at second main surface Job of silicon carbide substrate 10, Drain electrode 20 is made of a material capable of making ohmic contact with n type silicon carbide single-crystal substrate 11 such as NiSi (nickel silicide). Drain electrode 20 is electrically connected to silicon carbide single-crystal substrate 11.

Silicon carbide substrate 10 further includes an embedded region 17 having p type conductivity and an impurity concentration higher than in first base region 13. Embedded region 17 includes first embedded region portions 17a provided in first region R1, and second embedded region portions 17b provided in second region R2 and connected to first embedded region portions 17a. Embedded region 17 is a p type region including a p type impurity such as aluminum or boron. A concentration of the p type impurity such as aluminum included in embedded region 17 is, for example, 5×10¹⁷ cm⁻³ or more and 2×10¹⁸ cm⁻³ or less. First embedded region portions 17a are provided between. second main surface 10b and first base region 13a. First embedded region portions 17a. are provided to be sandwiched between a first lower drift region 12a1 and a first upper drift region 12a2. Embedded region portions 17a are preferably provided in positions facing first source regions 14a. First trench T1 may have a first trench portion Tit, and a second trench portion T12 separated from first trench portion T11 by first source region portion 14a2. Preferably, a value obtained by dividing a width a of embedded region 17 by a distance b from a center of the bottom of first trench portion T11 to a center of the bottom of second trench portion T12 in second direction a2 is 0.3 or less. Preferably, the value obtained by dividing width a of embedded region 17 by distance b from the center of the bottom of first trench portion T11 to the center of the bottom of second trench portion T12 in second direction a2 is 0.3 or more and 0.7 or less.

Referring to FIG. 2, embedded region 17 is provided to extend from between second main surface 10b and first base regions 13a to between upper electrode 16 and second main surface 10b. In other wards, embedded region 17 is provided to extend from directly below first base regions 13a provided in first region R1 to directly below second base regions 13b provided in second region R2. Second embedded region portions 17b are provided between contact region 18 and second main surface 10b. Preferably, embedded region 17 is electrically connected to upper electrode 16. Preferably, embedded region 17 is grounded together with upper electrode 16.

Referring to FIG. 1, embedded region 17 includes the plurality of first embedded region portions 17a. separated from one another by first drift region 12a. First embedded region portions 17a are provided at intervals along second direction a2. Preferably, the interval between first embedded region portions 17a in second direction a2 is equal to the interval between first source region portions 14a1, 14a2 and 14a3 in second direction a2.

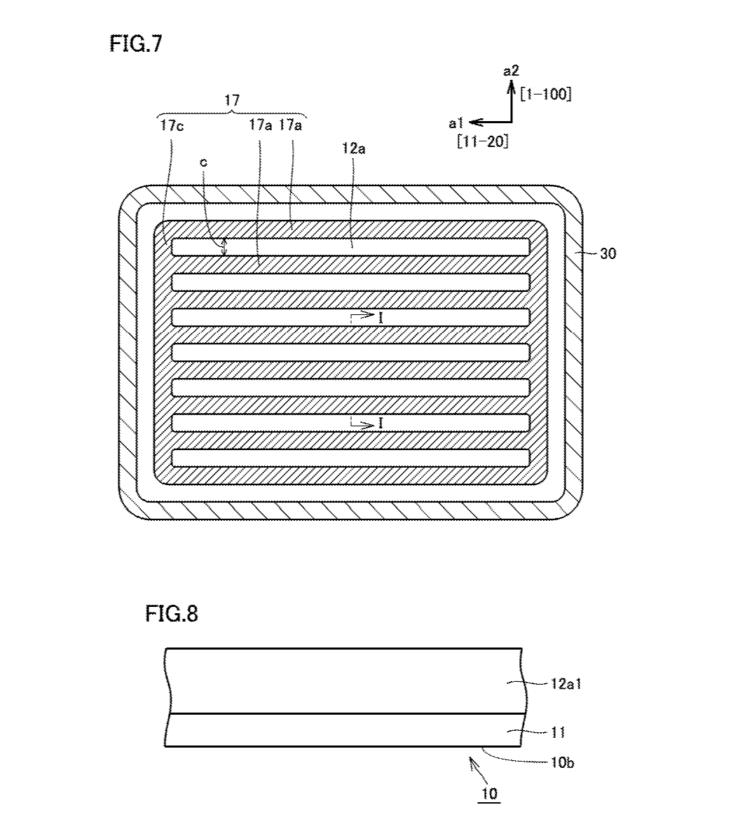

Referring to FIG. 7, when viewed two-dimensionally, the plurality of embedded region portions 17a are aligned with one another at regular intervals along second direction a2. First drift region 12a is partially provided to be sandwiched between the plurality of first embedded region portions 17a. A width c of the portion of first drift region 12a sandwiched between adjacent first embedded region portions 17a in second direction a2 is 1 μm or more and 3.5 μm or less. Preferably, width c is 1.0 μm or more and 2.5 μm or less. Embedded region 17 includes a third embedded region portion 17c which connects together end. portions on one side of the plurality of embedded region portions 17a and extends along second direction a2. Embedded region 17 includes a third embedded region portion 17c which connects together end portions on the other side of the plurality of embedded region portions 17a and extends along second direction a2. Embedded region 17 has the shape of a fence when viewed two-dimensionally. Silicon carbide substrate 10 may include a guard ring region 30 provided to surround embedded region 17 when viewed two-dimensionally. Guard ring region 30 is an impurity region having p type conductivity, for example.

Preferably, first direction a1 and second direction a2 are a <11-20> direction and a <1-100> direction, respectively, More preferably, first direction a1 and second direction a2 are a [11-20] direction and a [1-100] direction, respectively. First direction a1 and second direction a2 are only required to be the <11-20> direction and the <1-100> direction in terms of manufacturing design value, and manufacturing errors are allowed. First direction a1 may be a direction different from the <11-20> direction.

The operation of MOSFET 1 according to the first embodiment is now described. Referring to FIG. 1, when a voltage applied to gate electrode 27 is lower than a threshold voltage, namely, in an OFF state, even if a voltage is applied between source electrode 16 and drain electrode 20, a pn junction formed between first base region 13a and first drift region 12a is reverse biased, resulting in a non-conducting state. When a voltage equal to or higher than the threshold voltage is applied to gate electrode 27, on the other hand, an inversion layer is .formed in channel regions CH (see FIG. 4) near locations of first base regions 13a in contact with gate insulating film 15. As a result, source region 14 and first drill region 12a are electrically connected together, causing a current to flow between source electrode 16 and drain electrode 20. MOSFET 1 operates in this manner.

A method of manufacturing MOSFET 1 as a silicon carbide semiconductor device according to the first embodiment is now described.

A substrate is cut by slicing a silicon carbide single-crystal ingot grown by sublimation, for example, and then a surface of the substrate is mirror-polished, to prepare silicon carbide single-crystal substrate 11. Silicon carbide single-crystal substrate 11 is a hexagonal silicon carbide having a polytype of 4H, for example. The main surface of silicon carbide single-crystal substrate 11 has a diameter of, for example, 150 mm. The main surface of silicon carbide single-crystal substrate 11 is, for example, a {000-1} plane or a plane having an off angle of about 8° or less relative to the {000-1} plane.

Next, silicon carbide single-crystal substrate 11 is heated while a carrier gas including hydrogen, a source material gas including silane, propane, and a dopant gas including nitrogen are supplied to the main surface of silicon carbide single-crystal substrate 11. Consequently, first lower drift region 12a1 having it type conductivity is formed on silicon carbide single-crystal substrate 11, as shown in FIG. 8.

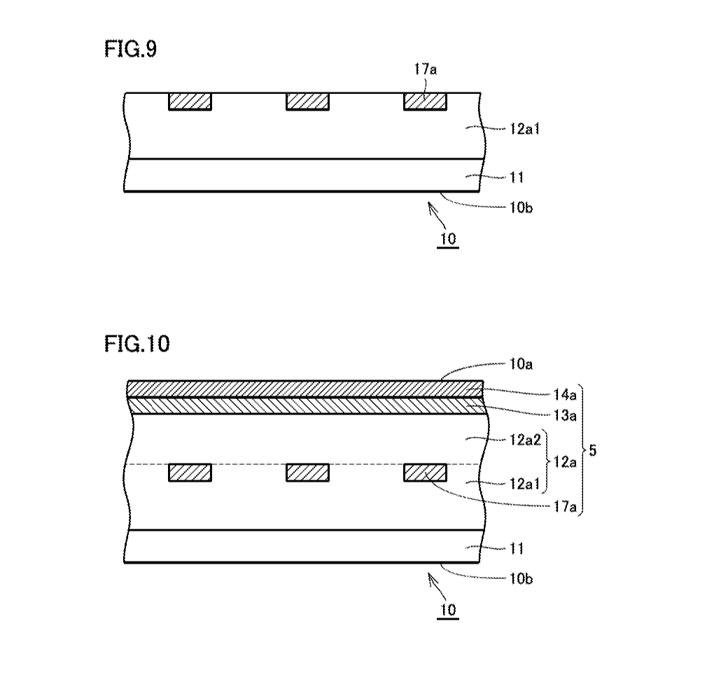

Next, an ion implantation mask (not shown) is formed on first lower drift region 12a1. Ions of a p type impurity such as aluminum are implanted into first lower drift region 12a1 through the ion implantation mask, to form the plurality of first embedded region portions 17a having p type conductivity (see FIG. 9).

Next, silicon carbide single-crystal substrate 11 is heated while a carrier gas including hydrogen, a source material gas including silane, propane, and a dopant gas including nitrogen are supplied. Consequently, first upper drift region 12a2 is formed on first lower drift region 12a1. Each of the plurality of first embedded region portions 17a is sandwiched between first lower drift region 12a1 and first upper drift region 12a2.

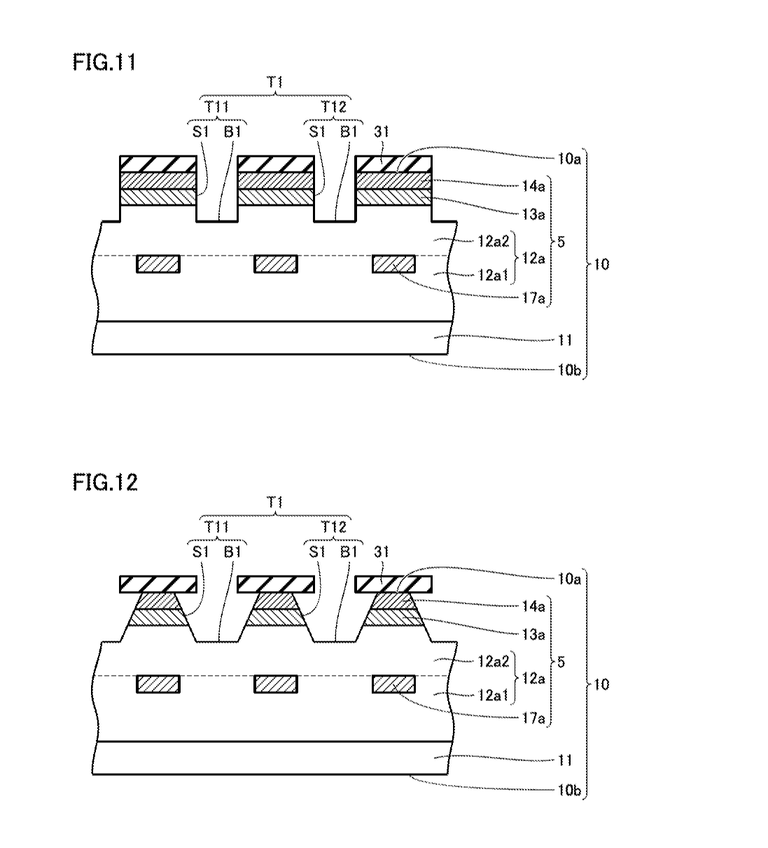

Next, ions of a p type impurity such as aluminum are implanted into first upper drift region 12a2, to form first base region 13a having p type conductivity. Then, ions of an n type impurity such as phosphorus are implanted. into an upper side of first base region. 13a, to form first source region 14a having n type conductivity. First source region 14a is formed to be separated from first drift region 12a by first base region 13a (see FIG. 10). Then, ions of a p type impurity such as aluminum are implanted into second source region 14b formed in second region R2, to form contact region 18 having p type conductivity (see FIGS. 2 and 3). Preferably, contact region 18 is formed only in second region R2, and not in first region R1.

Next, an activation annealing step is performed. Silicon carbide substrate 10 is heated for 30 minutes at a temperature of 1650° C. or more and 1750° C. or less, for example, in an argon atmosphere. Consequently, the p type impurity such as aluminum included in the base region, the n type impurity such as phosphorus included in source region 14, and the p type impurity such as aluminum included in contact region 18 are activated.

Referring to FIG. 1 a mask layer 31 is formed on first source region 14a. First source region 14a, first base region 13a, and part of first drift region 12a are removed by etching in openings of mask layer 31. The etching can be carried out, example, by performing inductive coupling plasma reactive ion etching using SF₆ or a mixed gas of SF₆ and O₂ as a reactive gas Consequently, in a region where first trench T1 (see FIG. 1) is to be formed, a recess T1 is formed having side surface S1 substantially perpendicular to first main surface 10a formed of first source region 14a, and bottom B1 substantially parallel to first main surface 10a. Likewise, in a region where second trench T2 (see FIG. 2) is to be formed, a recess (not shown is formed having a shape similar to that of recess T1.

Next, thermal etching is performed on silicon carbide substrate 10. The thermal etching can be performed, fib example, by beating in an atmosphere including a reactive gas having at least one or more types of halogen atoms. The at least one or more types of halogen atoms include at least one of chlorine (Cl) atoms and fluorine (F) atoms. This atmosphere is, for example, Cl₂, BCL₃, SF₆ or CF₄. The thermal etching is performed using a mixed gas of a chlorine as and an oxygen gas as a reactive gas, for example, at a thermal treatment temperature of 700° C. or more and 1000° C. or less, for example. It is noted that the reactive gas may include a carrier gas in addition to the chlorine gas and oxygen gas described above. As the carrier gas, for example, a nitrogen (N₂) gas, an argon gas, or a helium gas can be used. Side surface S1 of first trench T1 and side surface S2 of second trench T2 are each inclined relative to first main surface 10a such that the width of the trench increases toward the opening. Preferably, side surface S1 of first trench T1 and side surface S2 of second trench T2 are each inclined at 50° or more and 65° or less relative to the (000-1) plane.

Next, silicon carbide substrate 10 having first trench T1 and second trench T2 formed in first main surface 10a is placed in a heating furnace. By introducing oxygen into the heating furnace and oxidizing silicon carbide substrate 10 at a temperature of 1100° C. or more and 1200° C. or less, for example, gate oxidation film 15 is formed in contact with each of side surface S1 and bottom B1 of first trench T1, and each of side surface S2 and bottom 132 of second trench 11. Then, gate electrode 27, source electrode 16, interlayer insulating film 21, source wiring 24 and drain electrode 20 are each thrilled thereby manufacture MOSFET 1 shown in FIGS. 1 to 7.

A function and effect of MOSFET 1 as a silicon carbide semiconductor device according to the first embodiment is now described.

According to MOSFET 1 of the first embodiment, the on-resistance of MOSFET 1 can be reduced by partitioning silicon carbide substrate 10 into first region R1 where the channels are formed and second region R2 where upper electrode 16 is formed, and by disposing linear channel regions CH at high densities in first region R1 and disposing upper electrode 16 in second region R2. In addition, channel regions CH extend linearly along the first direction. Thus, there are fewer corner portions as compared to when channel regions CH have a polygonal shape. As a result, electric field concentration at the corner portions can be suppressed to thereby improve the breakdown voltage of MOSFET 1.

Moreover, according to MOSFET 1 of the first embodiment, between the plurality of first source region portions 14a1 and 14a2, first trench T1 is provided having first side surface S1 connected to first main surface 10a, and first bottom B I connected to first side surface S1. Gate insulating film 15 is in contact with first drill region 12a, first base region 13a, and the plurality of first source region portions 14a1, 14a2 at first side surface S1, and is in contact with first drift region 12a at first bottom B1. Channel region CH is in contact with gate insulating film 15 at first side surface S1. Consequently, the on-resistance of MOSFET 1 can be effectively reduced.

Moreover, according to MOSFET 1 of the first embodiment, in second region R2, second trench T2 is provided having second side surface S2 connected to first side surface S1 of first trench T1, and second bottom B2 connected to first bottom B1 of first trench T1. Second side surface S2 and second bottom 82 are each in contact with gate insulating film 15. Consequently, the on-resistance of MOSFET 1 can be more effectively reduced.

Moreover, MOSFET 1 according to the first embodiment further includes gate electrode 27 in contact with gate insulating film 15. Gate electrode 27 is provided in each of first trench T1 and second trench T2, and is also provided to traverse first trench T1 along second direction a2. Consequently, a gate electrode wiring can be formed to traverse first trench T1, thereby reducing the resistance of the gate electrode wiring.

Moreover, according to MOSFET 1 of the first embodiment, first trench T1 includes first trench portion T11, and second trench portion T12 separated from first trench portion T11 by first source region portion 14a2. Silicon carbide substrate 10 further includes embedded region 17 which is provided between second main surface 10b and first base region 13a, has p type conductivity, and has an impurity concentration higher than in first base region 13a. The value obtained by dividing. width a of embedded region portion 17a by distance b from the center of the bottom of first trench portion T11 to the center of the bottom of second trench portion T12 in the second direction is 0.3 or less. Consequently, the on-resistance of MOSFET 1 can be effectively reduced while the breakdown voltage of MOSFET 1 is maintained at a high level.

Moreover, according to MOSFET 1 of the first embodiment, silicon carbide substrate 10 further includes embedded region 17 which is provided between. second main surface 10b and first base region 13a, has p type conductivity, and has an impurity concentration higher than in first base region 13a. Consequently, the breakdown voltage of the silicon carbide semiconductor device can be improved.

Moreover, according to MOSFET 1 of the first embodiment, embedded region 17 is provided to extend from between second main surface 10b and first base region 13a to between upper electrode 16 and second main surface 10b. Consequently, energy during application of a high electric filed can be released as a current to upper electrode 16.

Moreover, according to MOSFET 1 of the first embodiment, embedded region 17 is electrically connected to upper electrode 16. Consequently, energy during application of a high electric tiled can be effectively released as a current to upper electrode 16.

Moreover, according to MOSFET 1 of the first embodiment, when viewed along the first direction, embedded region 17 includes the plurality of embedded region portions 17a separated from one another by first drift region 12a. Width c of a portion of first drift region 12a sandwiched between adjacent embedded region portions 17a in the direction along the second direction is 1 μm or more and 3.5 μm or less. Consequently, the breakdown voltage of MOSFET 1 can be improved.

Moreover, according to MOSFET 1 of the first embodiment, the first direction is the <11-20> direction. Consequently, a current can flow through channel region CH in the <1-100> direction, thereby effectively reducing the channel resistance. In addition, misalignment in the second direction can be reduced.

### Second Embodiment

The configuration of a MOSFET as silicon carbide semiconductor device 1 according to a second embodiment of the present invention is now described. The MOSFET according to the second embodiment is mainly different from the MOSFET according to the first embodiment in that first trench T1 is replaced by first drift region 12a and second trench T2 is replaced by second drift region 12b. The configuration is otherwise substantially the same as that of the MOSFET according to the first embodiment. Thus, the same or corresponding parts are designated by the same reference numbers and the descriptions thereof will not be repeated.

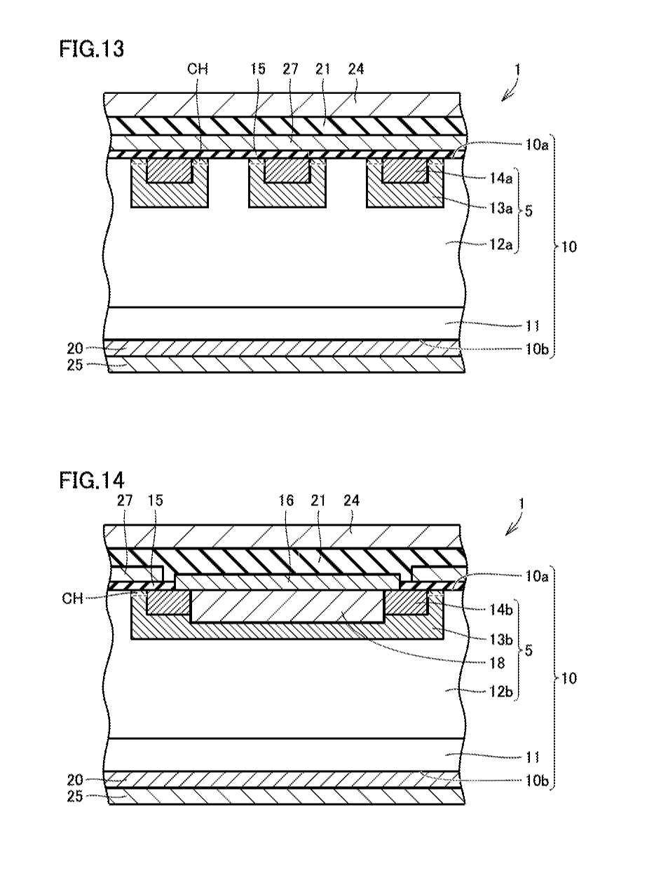

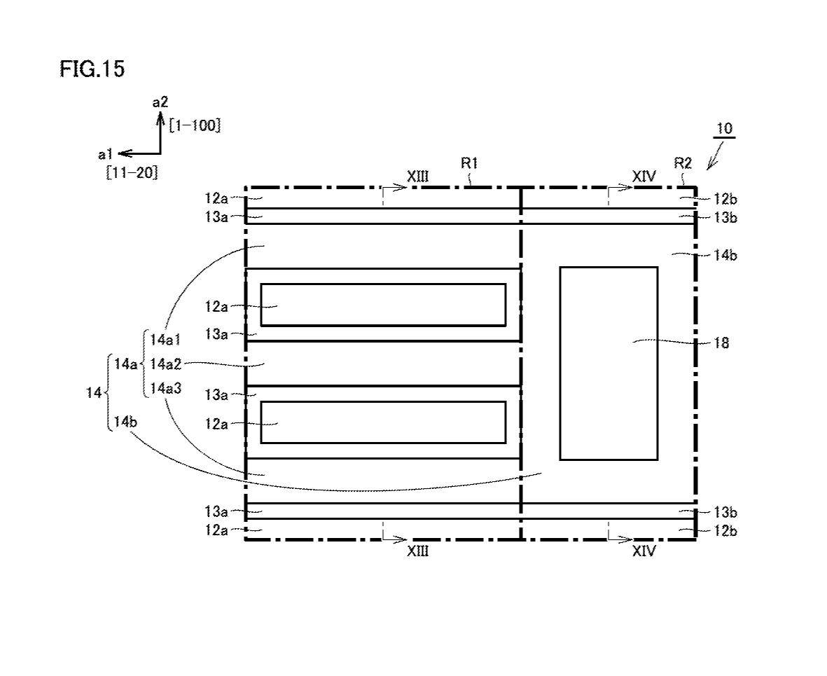

FIGS. 13 and 14 are schematic sectional views of the silicon carbide semiconductor device according to the second embodiment, and FIG. 15 is a schematic plan view of a silicon carbide substrate included in the silicon carbide semiconductor device. FIG. 13 is a schematic sectional view showing the structure of the silicon carbide semiconductor device when viewed along line XIII-XIII in FIG. 15. FIG. 14 is a schematic sectional view showing the structure of the silicon carbide semiconductor device when viewed along line XIV-XIV in FIG. 15.

Referring to FIGS. 13 to 18, the silicon carbide semiconductor device according to the second embodiment is a planar MOSFET. That is, first trench T1 and second trench T2 are not provided in first main surface 10a of silicon carbide substrate 10. Referring to FIG. 13, first trench T1 is replaced by first drift region 12a. Referring to FIG. 14, second trench T2 is replaced by second drift region 12b.

Referring to FIG. 13, gate insulating film 15 is in contact with first source regions 14a, first base regions 13a, and first drift region 12a at first main surface 10a of silicon carbide substrate 10. Gate insulating film 15 may be provided to cover the entire first main surface 10a of first region R1. First drift region 12a is provided between adjacent first base regions 13a. A portion of first drift region 12a provided between adjacent first base regions 13a is a JFET (Junction Field Effect Transistor) region. Referring to FIG. 14, gate insulating film 15 is in contact with second source regions 14b, second base region 13b, and second drift region 12b at first main surface 10a of silicon carbide substrate 10. Gate insulating film 15 may be in contact with source electrode 16 on second region R2.

Referring to FIG. 15, first source region 14a includes the plurality of first source region portions 14a1, 14a2 and 14a3. First drift region 12a is provided between two adjacent first source region portions. Gate insulating film 15 is in contact with the plurality of first source region portions 14a1, 14a2 and 14a3 at first main surface 10a. The portion of first drift region 12a exposed at first main surface 10a in first region, R1 is provided to be surrounded by first base region 13a when viewed two-dimensionally. The portion of first drift region 12a exposed at first main surface 10a in first region R1 is provided to extend in first direction a1 when viewed two-dimensionally. When viewed two-dimensionally, the width of a portion of first drift region 12a along first direction a1 is greater than the width of a portion of first drift region 12a along second direction a2 parallel to first main surface 10a. and perpendicular to first direction a1. The portions of first drift regions 12a exposed at first main surface 10a are provided in alignment with one another along second direction a2.

Referring to FIG. 15, the portions of second drift regions 12 exposed at first main surface 10a are connected to the portions of first drift regions 12a exposed at first main surface 10a at the boundary between first region R1 and second region R2. Likewise, second base regions 13b are connected to first base regions 13a at the boundary between first region R1 and second region R2. Referring to FIG. 15, contact region 18 and second source region 14b are provided between the plurality of second base regions 13b in second region R2. Contact region 18 is not provided in first region R1. Contact region 18 is provided to be surrounded by second source region 14b when viewed two-dimensionally. The width, of contact region 18 along first direction a1 may be smaller than the width of contact region 18 along second direction a2. Second source region 14h is provided to connect together the plurality of first source region portions 14a1, 14a2 and 14a3 provided in first region R1. The plurality of first source region portions 14a1, 14a2 and 14a3 are each in contact with second source region 14b at the boundary between first region R1 and second region R2.

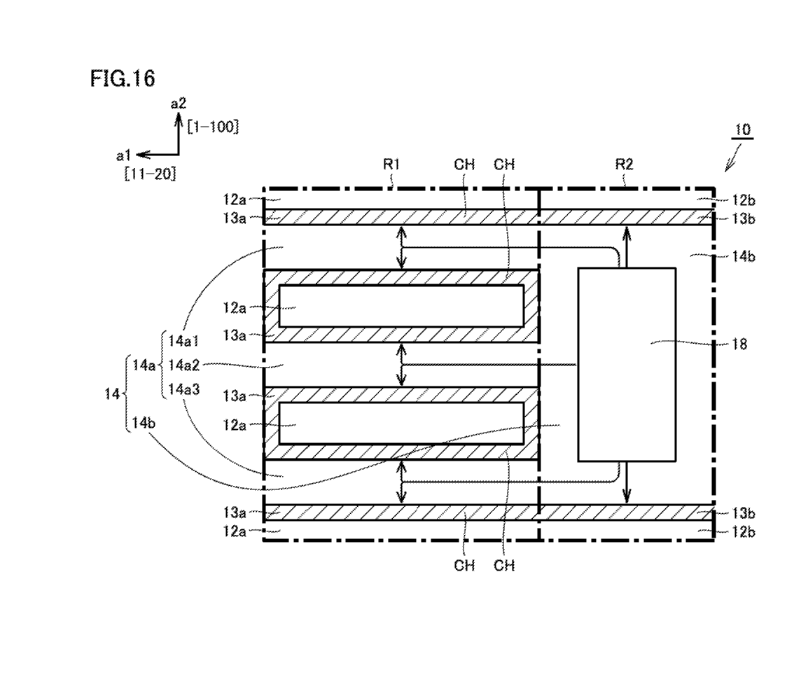

Referring to FIG. 16, the configuration of the channel region of the MOSFET is described. In FIG. 16, regions marked with diagonal lines are channel regions CH. When viewed along the direction perpendicular to first main surface 10a, channel regions CH each have a portion extending, linearly along the first direction. Channel region CH may be thrilled to surround first drift region 12a when viewed two-dimensionally. That is, channel region CH has a portion extending linearly along first direction a1, and a portion extending linearly along second direction a2, Channel region CH is provided between first drift region 12a and first source region 14a, as well as between first drift region 12a and second source region 14b. Channel region CH may be provided between second drift region 12b and second source region 14b.

Arrows in FIG. 16 indicate a current flow during ON time. A current flows from source electrode 16 provided on contact region 18 and second source region 14b in second region R2 toward second source region 14b. The current partially flows along first direction a1 from second source region 14b toward first source region 14a. The current passes through channel regions CH along second direction a2 perpendicular to first direction a1. The current flows from first source region 14a toward first drift regions 12a through channel regions CH. The current partially passes through channel regions CH in second region R2, and flows toward second drift regions 12b.

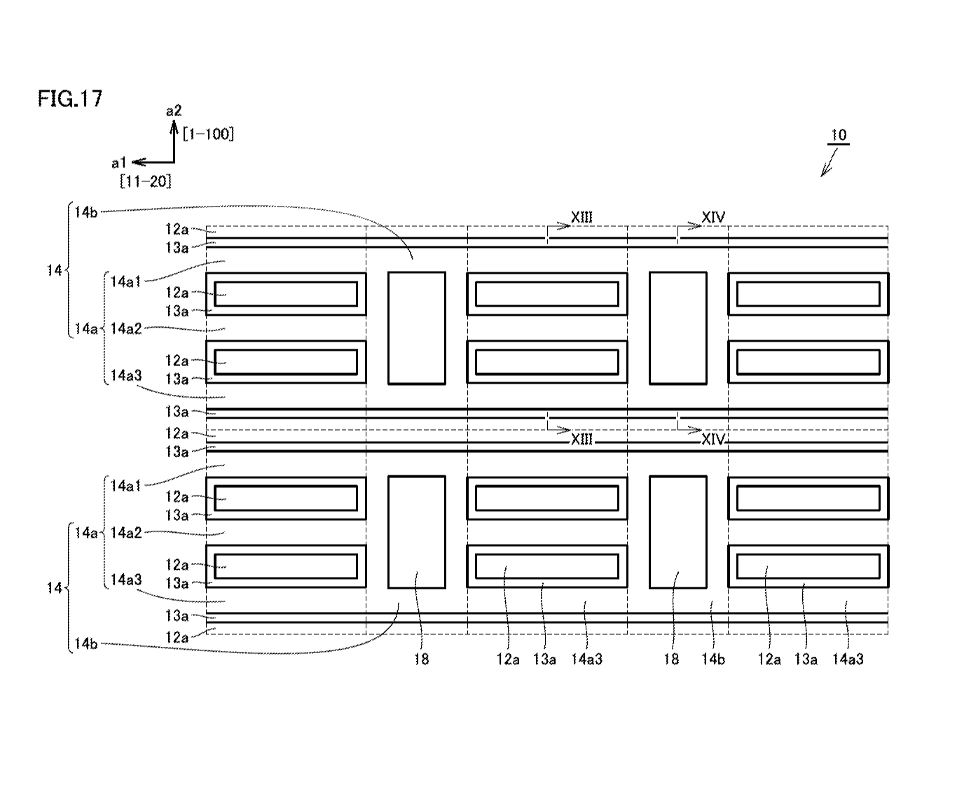

Referring to FIG. 17, silicon carbide substrate 10 may be formed of a plurality of units, each including first region R1 and second region R2, which are aligned with one another along each of first direction a1 and second direction a2. Specifically, first regions R1 and second regions R2 are alternately disposed along first direction a1. First regions R1 are repeatedly disposed and second regions R2 are repeatedly disposed along the second direction. First drift regions 12a are provided on opposing sides of contact region 18 in the direction along first direction a1. Second drift regions 12b are provided on opposing sides of contact region 18 in the direction along second direction a2. First drift regions 12a are provided at intervals in the direction along first direction a1. First drift regions 12a are provided at intervals in the direction along second direction a2. The distance between two adjacent first drift regions 12a in the direction along first direction a1 may be greater than the distance between two adjacent second drift regions 12b in the direction along second direction a2.

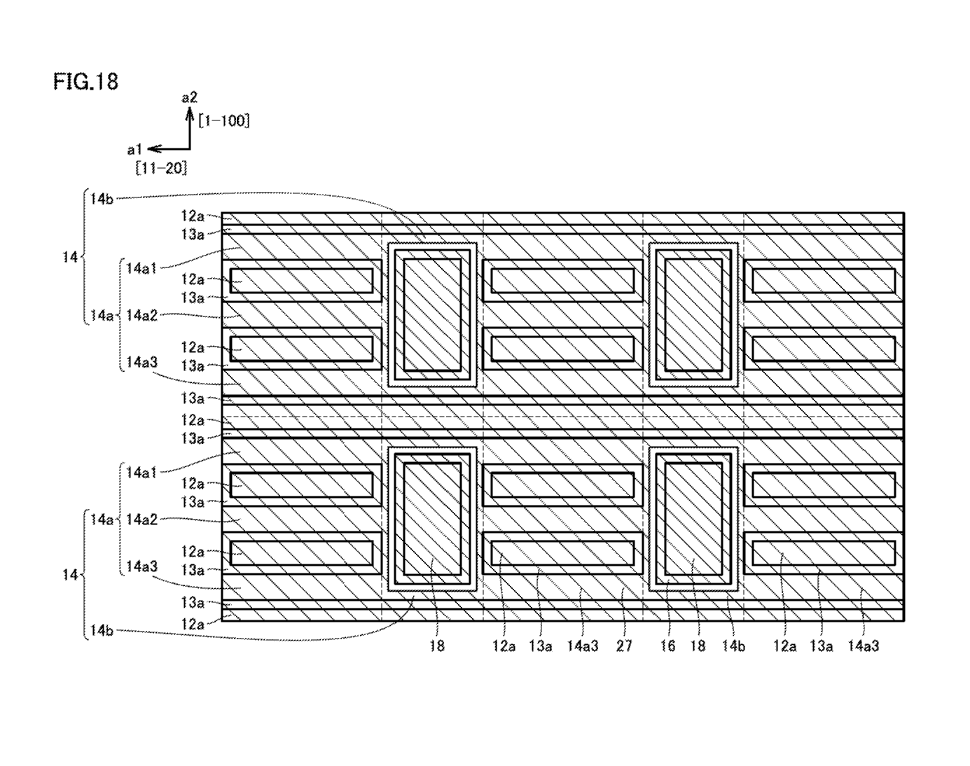

Referring to FIG. 13, gate electrode 27 is provided to face first drift region 12a, first base regions 13a, and first source regions 14a. Referring to FIG. 14, gate electrode 27 is provided to face second drift region 12b, second base region 13b, and second source regions 14b. Referring to FIG. 18, gate electrode 27 is provided to surround source electrode 16 when viewed two-dimensionally. Gate electrode 27 may be provided to cover the entire first region R1 and also to cover part of second region R2. Gate electrode 27 may be provided in a mesh-like manner when viewed two-dimensionally. Gate electrode 27 is provided to traverse each of the portions of the plurality of first drift regions 12a exposed at first main surface 10a along second direction a2. Gate electrode 27 is provided to traverse each of the portions of the plurality first source region portions 14a1, 14a2 and 14a3 (see FIG. 15) along second direction a1

A function and effect of MOSFET 1 as a silicon carbide semiconductor device according to the second embodiment is now described.

According to MOSFET 1 of the second embodiment, first drift region 12a is provided between the plurality of first source region portions 14a1 and 14a2. Gate insulating film 15 is in contact with first drift region 12a first base regions 13a, and the plurality first source region portions 14a1, 14a2 at first main surface 10a Consequently, the on-resistance of planar MOSFET 1 can be reduced.

Although the first conductivity type has been described as n type conductivity and the second conductivity type as p type conductivity in the above embodiments, the first conductivity type may be p type conductivity and the second conductivity type may be n type conductivity. Although the MOSFET has been described as an example of the silicon carbide semiconductor device, the silicon carbide semiconductor device may be an IGBT (Insulated Gate Bipolar Transistor) or the like.

### Examples

In examples, relation between area occupancy of the embedded region and specific on-resistance was examined using MOSFET 1 in the first embodiment shown. in FIG. 1, by measuring a value of the specific on-resistance of MOSFET 1, while varying a value (hereinafter referred to as area occupancy of the embedded region) obtained by dividing, width a of first embedded region portion 17a of MOSFET 1 by distance b from the center of the bottom of first trench portion T11 to the center of the bottom of second trench portion T12 in the second direction. First embedded region, portion 17a, first trench portion T11 and second trench portion T12 each extend along first direction a1. Accordingly, the value obtained by dividing width a of first embedded region portion 17a of MOSFET 1 by distance b from the center of the bottom of first trench portion T11 to the center of the bottom of second trench portion T12 in the second direction when viewed in cross section is equal to a ratio of the area of first embedded region portion 17a to the area of a region (cell region) sandwiched between the center of the bottom of first trench portion T11 and the center of the bottom of second trench portion 112 when viewed two-dimensionally.

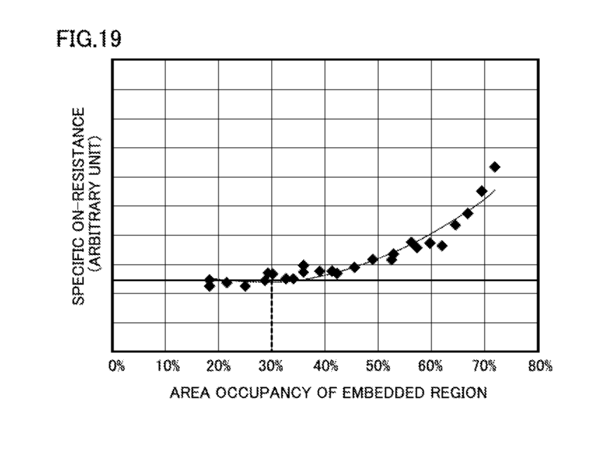

Referring to FIG. 19, the relation between the area occupancy of the embedded. region and the specific on-resistance of the MOSFET is described. In FIG. 19, a horizontal axis represents the area occupancy of the embedded region and a vertical axis represents the specific on-resistance of the MOSFET. In an area where the area occupancy of the embedded region is higher than 30% and lower than or equal to 72%, the specific on-resistance, of the MOSFET decreases as the area occupancy of the embedded region decreases. When the area occupancy of the embedded region becomes lower than or equal to 30%, on the other hand, the specific on-resistance maintains constant values without decreasing. In an area where the area occupancy of the embedded region is higher than or equal to about 18% and lower than or equal to about 30%, the specific on-resistance exhibits substantially similar values. It was determined from the above results that the specific on-resistance of the MOSFET can be effectively reduced by setting the area occupancy of the embedded region to lower than or equal to 30%.

Although the embodiments of the present invention have been described above, it should be understood that the embodiments disclosed herein are illustrative and non-restrictive in every respect. The scope of the present invention is defined by the terms of the claims, and is intended to include any modifications within the scope and meaning equivalent to the terms of the claims.

1. A silicon carbide semiconductor device, comprising a silicon carbide substrate having a first main surface and a second main surface opposite to said first main surface,
said silicon carbide substrate including a first impurity region having a first conductivity type, a second impurity region being in contact with said first impurity region and having a second conductivity type different from said first conductivity type, and a third impurity region having said first conductivity type, being separated from said first impurity region by said second impurity region, and forming said first main surface,
said silicon carbide substrate being formed of a first region and a second region adjacent to each other when viewed from a direction perpendicular to said first main surface,
said first region including said first impurity region, said second impurity region, and a first portion forming part of said third impurity region,
said second region including a second portion, said second portion forming part of said third impurity region and being connected to said first portion,
said silicon carbide semiconductor device further comprising:
a gate insulating film in contact with said first impurity region, said second impurity region, and said first portion of said third impurity region;
an upper electrode disposed on said second portion of said second region; and
a lower electrode disposed on said second main surface,
said second impurity region having a channel region in contact with said gate insulating film,
said channel region extending linearly along a first direction when viewed along said direction perpendicular to said first main surface,
said first portion of said third impurity region including a plurality of impurity region portions disposed in alignment with each other along a second direction, said second direction being parallel to said first main surface and perpendicular to said first direction,
said second portion being provided to connect said plurality of impurity region portions together,
wherein a first trench having a first side surface connected to said first main surface and a first bottom connected to said first side surface is provided between said plurality of impurity region portions,
said gate insulating film is in contact with said first impurity region, said second impurity region, and said plurality of impurity region portions at said first side surface, and is in contact with said first impurity region at said first bottom,
said channel region is in contact with said gate insulating film at said first side surface,
a second trench having a second side surface directly connected to said first side surface of said first trench and a second bottom directly connected to said first bottom of said first trench is provided in said second region, and
said second side surface and said second bottom are each in contact with said gate insulating film.

2. (canceled)

3. (canceled)

4. The silicon carbide semiconductor device according to claim 1, further comprising a gate electrode in contact with said gate insulating film, wherein
said gate electrode is provided in each of said first trench and said second trench, and is also provided to traverse said first trench along said second direction.

5. The silicon carbide semiconductor device according to claim 1, wherein
said first trench includes a first trench portion, and a second trench portion separated from said first trench portion by one of said impurity region portions,
said silicon carbide substrate further includes an embedded region, said embedded region being provided between said second main surface and said second impurity region, having said second conductivity type, and having an impurity concentration higher than in said second impurity region, and
a value obtained by dividing the width of said embedded region by the distance from a center of the bottom of said first trench portion to a center of the bottom of said second trench portion in said second direction is 0.3 or less.

6. The silicon carbide semiconductor device according to claim 1, wherein
said silicon carbide substrate further includes an embedded region, said embedded region being provided between said second main surface and said second impurity region, having said second conductivity type, and having an impurity concentration higher than in said second impurity region.

7. The silicon carbide semiconductor device according to claim 6, wherein
said embedded region is provided to extend from between said second main surface and said second impurity region to between said upper electrode and said second main surface.

8. The silicon carbide semiconductor device according to claim 6, wherein
said embedded region is electrically connected to said upper electrode.

9. The silicon carbide semiconductor device according to claim 6, wherein
said embedded region includes a plurality of embedded region portions separated from each other by said first impurity region when viewed along said first direction, and
the width of a portion of said first impurity region sandwiched between adjacent said embedded region portions in a direction along said second direction is 1 μm or more and 3.5 μm or less.

10. The silicon carbide semiconductor device according to claim 1, wherein
said first impurity region is provided between said plurality of impurity region portions, and
said gate insulating film is in contact with said first impurity region, said second impurity region, and said plurality of impurity region portions at said first main surface.

11. The silicon carbide semiconductor device according to claim 1, wherein
said first direction is a <11-20> direction.
